(19) United States
(12) Patent Application Publication
(10) Pub. No.: US 2012/0286390 A1
(43) Pub. Date: Nov. 15, 2012

(54) ELECTRICAL FUSE STRUCTURE AND METHOD FOR FABRICATING THE SAME

(76) Inventors: Kuei-Sheng Wu, Tainan City (TW); Ching-Hsiang Tseng, Tainan City (TW); Chang-Chien Wong, Tainan City (TW); Wai-Yi Lien, Hsinchu City (TW)

(21) Appl. No.: 13/227,492

(22) Filed: Sep. 8, 2011

Related U.S. Application Data
(60) Provisional application No. 61/484,684, filed on May 11, 2011.

(51) Int. Cl. H01L 23/525; H01L 21/768

(52) U.S. Cl. 257/529; 438/601; 257/E23.149; 257/E21.592

(57) ABSTRACT

An electrical fuse structure includes a top fuse, a bottom fuse and a via conductive layer positioned between the top fuse and the bottom fuse for providing electric connection. The top fuse includes a top fuse length and the top fuse length is equal to or larger than a predetermined value. The bottom fuse includes a bottom fuse length larger than the top fuse length.

### CROSS REFERENCE TO RELATED APPLICATIONS

This application is a non-provisional of U.S. Provisional Application No. 61/484,684, entitled “Electrical e-fuse structure and method for fabricating the same”, which was filed on May 11, 2011.

### BACKGROUND OF THE INVENTION

1. Field of the Invention

The present invention relates to an electrical fuse (hereinafter abbreviated as e-fuse) and a method for fabricating the same, and more particularly, to an e-fuse having a larger blowing window and a method for fabricating the same.

2. Description of the Prior Art

As semiconductor processes become smaller and more complex, semiconductor components are influenced by impurities more easily. For example, the whole chip may be unusable once a single metal link, a diode, or a MOS is broken down. As a countermeasure against to the problems, there have been proposed fuses that can be selectively blown for increasing the yield of IC manufacturing.

In general, fuse circuits are electrically connected to redundant circuits of an IC. When defects are found in the circuit, fuses can be selectively blown for repairing or replacing the defective circuits. In addition, fuses provide the function of programming circuits for various customized functions.

On the other hand, fuses are classified into two categories based on their operation: thermal fuse having the open circuit condition provided by Laser zip and e-fuse having the open circuit condition provided by proper circuit generating electro-migration (EM) effect. The e-fuse for semiconductor devices may be classified into categories of poly e-fuse, MOS capacitor anti-fuse, diffusion fuse, contact e-fuse, contact anti-fuse, and the like.

### SUMMARY OF THE INVENTION

According to an aspect of the present invention, an e-fuse structure is provided. The e-fuse includes a top fuse having a top fuse length, a bottom fuse having a bottom fuse length, and a via conductive layer positioned between the top fuse and the bottom fuse for electrically connecting the top fuse and the bottom fuse. The top fuse length is equal to or larger than a predetermined value, and the bottom fuse length is larger than the top fuse length.

According to another aspect of the present invention, a method for fabricating an e-fuse structure is provided. The method includes providing a substrate, forming a first metal interconnection layer and a bottom fuse having a bottom fuse length on the substrate, forming a second metal interconnection layer, a top fuse having a top fuse length, and a via conductive layer on the substrate. The top fuse length is equal to or larger than a predetermined value, and the bottom fuse length is larger than the top fuse length.

According to the e-fuse structure and the method for fabricating the same provided by the present invention, the top fuse length and the bottom fuse length are decided according to the position where the blowing point is to be formed: When the bottom fuse length is larger than the top fuse length, it is ensured that the blowing point is formed in the bottom fuse. Furthermore, in the condition that the bottom fuse length is larger than the top fuse length, the bottom fuse length and the top fuse length are further adjusted and formed such that the blowing point is formed near a boundary between the bottom fuse and the via conductive layer. Consequently, the size of the e-fuse structure is shrunk and the blowing window is increased.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a blowing mechanism of an e-fuse structure.

FIG. 2 is a schematic drawing illustrating an e-fuse structure provided by a preferred embodiment of the present invention.

FIGS. 3-4 are schematic drawings illustrating a method for fabricating an e-fuse structure provided by the preferred embodiment of the present invention, wherein

FIG. 3 is a cross-sectional view taken along line A-A′ of FIG. 2, and

FIG. 4 is cross-sectional view in a step subsequent to FIG. 3.

FIG. 5 is a schematic drawing respectively illustrating the e-fuse structure of the preferred embodiment after performing a blowing process.

FIG. 6 is another schematic drawing respectively illustrating the e-fuse structure of the preferred embodiment after performing a blowing process.

FIG. 7 illustrates the relationship of metal fuse resistance between before and after a high temperature storage lifetime (HTSL) test.

### DETAILED DESCRIPTION

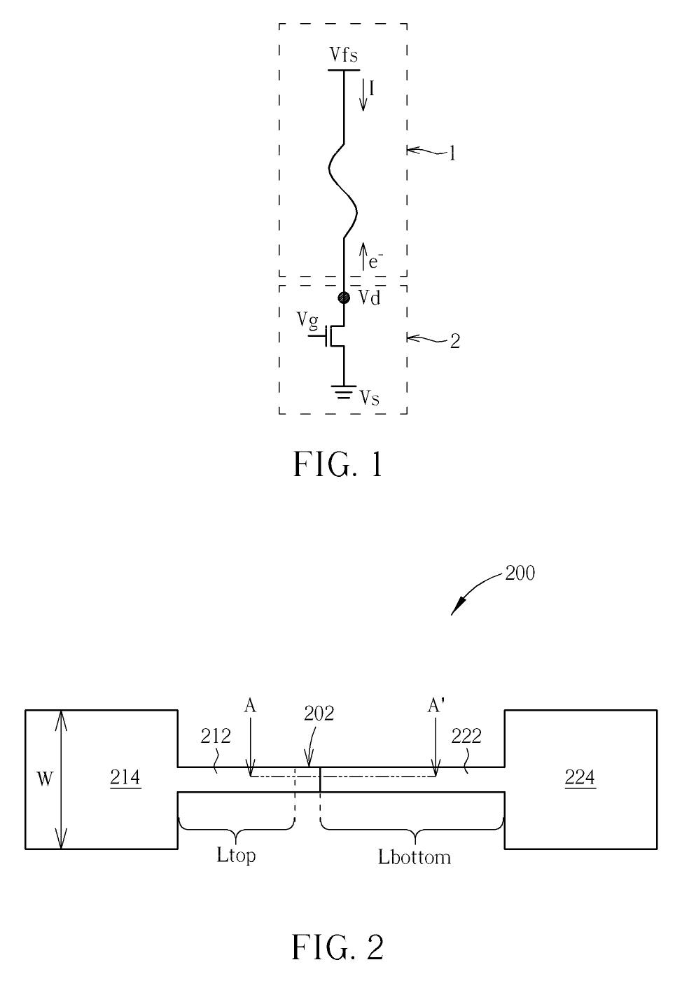

A blowing mechanism of an e-fuse structure is typically shown in FIG. 1. The cathode of an e-fuse structure 1 is electrically connected to the drain of a blowing device such as a transistor 2. A voltage Vfs is applied to the anode of the e-fuse structure 1, a voltage Vg is applied to the gate of the transistor 2, and a voltage Vd is applied to the drain of the transistor 2, respectively. The source of the transistor 2 is grounded. The electric current (I) is from the anode of the e-fuse structure 1 to the cathode of the e-fuse structure 1; and the electrons flow (e⁻) is from the cathode of the e-fuse structure 1 to the anode of the e-fuse structure 1. The electric current suitable for the blowing is in a proper range. If the electric current is too low, the electron-migration effect is not completed, and if it is too high, the e-fuse structure 1 tends to be thermally ruptured. In general, the blowing current for an e-fuse structure made by a 32/28 nanometer (nm) manufacturing process is between 21.6 milliampere (mA) and 30 mA.

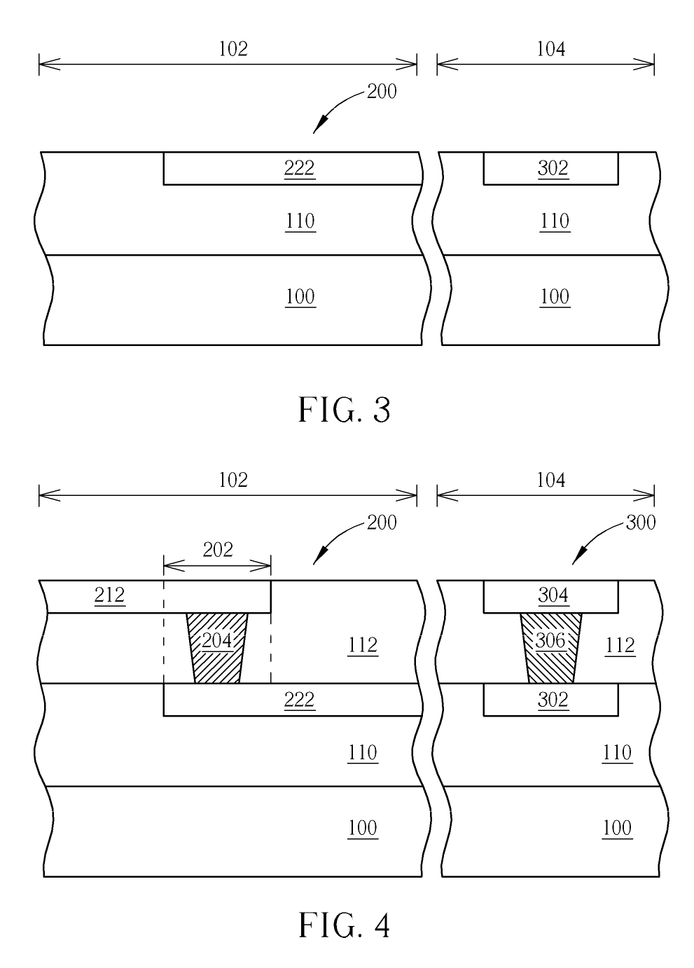

Please refer to FIG. 2 and FIGS. 3-4, wherein FIG. 2 is a schematic drawing illustrating an e-fuse structure provided by a preferred embodiment of the present invention, and FIGS. 3-4 are schematic drawings illustrating a method for fabricating an e-fuse structure provided by the preferred embodiment of the present invention. Furthermore, FIGS. 3-4 are cross-sectional views taken along line A-A′ of FIG. 2. As shown in FIG. 2 and FIG. 3, the preferred embodiment first provides a substrate 100 having an e-fuse region 102 and an interconnection region 104 (show in FIG. 3). Then, a first dielectric layer 110 is formed on the substrate 100. The first dielectric layer 110 can include low dielectric constant (low-k) material selected from the group consisting of silicon oxide, silicon nitride, silicon carbon nitride, silicon carbide, tetraethylorthosilicate (TEOS), borophosphosilicate glass (BPSG), and undoped silicate glass (USG). Next, a damascene process is performed to form a bottom fuse 222 and an anode 224 (show in FIG. 2 only) of an e-fuse structure 200 in the first dielectric layer 110, and simultaneously to form a first metal interconnection layer 302 in the first dielectric layer 110. As shown in FIG. 3, the bottom fuse 222 and the anode 224 of the e-fuse structure 200 are formed in the e-fuse region 102 while the first metal interconnection layer 302 is formed in the interconnection region 104. Furthermore, the bottom fuse 222 is electrically connected to the anode 224. As shown in FIG. 3, since the first metal interconnection layer 302, the bottom fuse 222 and the anode 224 are formed by the same damascene process, the first metal interconnection layer 302, the bottom fuse 222 and the anode 224 are all coplanar. The first metal interconnection layer 302 is electrically isolated from the e-fuse structure 200 (including the bottom fuse 222 and the anode 224).

Please refer to FIG. 2 and FIG. 4. Next, a second dielectric layer 112 is formed on the first dielectric layer 110. The second dielectric layer 112 can include low-k material the same with the first dielectric layer 110. Subsequently, a dual damascene process is performed to form a top fuse 212, a cathode 214 (shown in FIG. 2 only) of the e-fuse structure 200 in the second dielectric layer 112, and simultaneously to form a second metal interconnection layer 304 in the second dielectric layer 112. As shown in FIG. 4, the top fuse 212 and the cathode 214 of the e-fuse structure 200 are formed in the e-fuse region 102 while the second metal interconnection layer 304 is formed in the interconnection region 104. The top fuse 212 is electrically connected to the cathode 214. Furthermore, a via conductive layer 204 is formed in an overlapping region 202 of the top fuse 212 and the bottom fuse 222 in the e-fuse region 102 by the dual damascene process. The via conductive layer 204 is provided to electrically connect the top fuse 212 and the bottom fuse 222. Accordingly, the e-fuse structure 200 is completed. In addition, another via conductive layer 306 can be formed in the second dielectric layer 112 by the damascene process to provide electrical connection between the first metal interconnection layer 302 and the second metal interconnection layer 304. Accordingly, a metal interconnection structure 300 is completed, and the second metal interconnection layer 304 of the metal interconnection structure 300 is stacked on the first metal interconnection layer 302. As shown in FIG. 4, since the second metal interconnection layer 304, the top fuse 212 and the cathode 214 are formed by the same dual damascene process, the second metal interconnection layer 304, the top fuse 212 and the cathode 214 are all coplanar. The second metal interconnection layer 304 is electrically isolated from the e-fuse structure 200 (including the top fuse 212 and the cathode 214). In addition, the cathode 214 of the e-fuse structure 200 is electrically connected to a blowing device (not shown) and a voltage Vfs is applied to the anode 224 as mentioned above.

It should be noted that the first dielectric layer 110, the second dielectric layer 112, the first metal interconnection 302, and the second metal interconnection 304 mentioned in the preferred embodiment are only used to distinguish one element from another element. In other words, the e-fuse structure 200 of the preferred embodiment can be formed simultaneously with any two metal interconnections of the metal interconnection structure 300, thus the top fuse 212 and the bottom conductive pattern 222 are respectively coplanar with an upper metal interconnection and a lower metal interconnection. Because the e-fuse structure 200 is formed by the damascene process, the e-fuse structure 200 can include material the same with the first metal interconnection layer 302 and the second metal interconnection layer 304, such as copper, aluminum, or tungsten. Furthermore, the top fuse 212 and the bottom fuse 222 can include widths identical to each other or different from each other. The top fuse 212 and the bottom fuse 222 also can include thicknesses identical to each other or different from each other.

Please refer to FIG. 2 and FIG. 4 again. When forming the e-fuse structure 200 of the preferred embodiment, the top fuse 212 includes a top fuse length Lₜₒₚ and the bottom fuse 222 includes a bottom fuse length L_{bottom}. As shown in FIG. 2, the top fuse length Lₜₒₚ and the bottom fuse length L_{bottom} never include the overlapping region 202. More important, the top fuse length Lₜₒₚ is equal to or larger than a predetermined value L and the bottom fuse length L_{bottom} is equal to larger than the top fuse length Lₜₒₚ according to the method provided by the preferred embodiment. In the preferred embodiment, when a width of the top fuse 212 and the bottom fuse 222 is 0.66 micrometer (μm), and a thickness of the top fuse 212 and the bottom fuse 222 is 0.14 μm, the predetermined value L is preferably 0.77 μm, but not limited to this. Furthermore, when the top fuse length Lₜₒₚ is 0.77 μm, the bottom fuse length L_{bottom} is 1 to 4 times the top fuse length Lₜₒₚ.

It is noteworthy that when the top fuse 212 includes the width and thickness as mentioned above but has the top fuse length Lₜₒₚ smaller than the predetermined value L, a blech effect occurs to the e-fuse structure 200: When the electrons flow (e⁻) flows from the cathode 214 to the top fuse 212, the via conductive layer 204 and the bottom fuse 222, a mechanical stress opposite to the electrons flow is generated in the e-fuse structure 200, consequently metal atoms are forced opposite to the direction of the electrons flow, thus more blowing current is required to blow out the e-fuse structure. It is found that the blech effect is more serious when the fuse length is getting smaller and thus the minimum blowing current is exemplarily increased to be higher than 25 mA. In other words, the blech effect in short fuse length narrows the blowing window.

Therefore, the top fuse length Lₜₒₚ is defined to be equal to or larger than the predetermined value L in the preferred embodiment while the bottom fuse length L_{bottom} is equal to larger than the top fuse length Lₜₒₚ. Thus the blech effect is avoided. Please refer to Table 1, which is a summary table of the e-fuse structure 200 having different bottom fuse length L_{bottom}:

TABLE 1

| Split | Top Fuse | Bottom Fuse | minimum blowing |
|---|---|---|---|
| No. | Length Lₜₒₚ | Length L_{bottom} | current (mA) |
| D | L | L | 21 |
| E | L | 2L | 21 |
| F | L | 3L | 21 |
| G | L | 4L | 21 |

It should be noted that the top fuse length Lₜₒₚ in Table 1 is equal to the predetermined value L, which is 0.77 μm. It also should be understood that when the widths and thickness of the top fuse 212 and the bottom fuse 222 are changed according to different product requirement, the predetermined value L is changed accordingly as long as the top fuse length Lₜₒₚ is equal to or larger than the predetermined value L. In Accordance with Table 1, when the top fuse length Lₜₒₚ is equal to or larger than the predetermined value L, the minimum blowing current is reduced to 21 mA, it is found that the minimum blowing current can be further reduced even to 18.15 mA. It is concluded that the e-fuse structure 200 provided by the preferred embodiment fulfills requirement to the blowing window of the e-fuse structure.

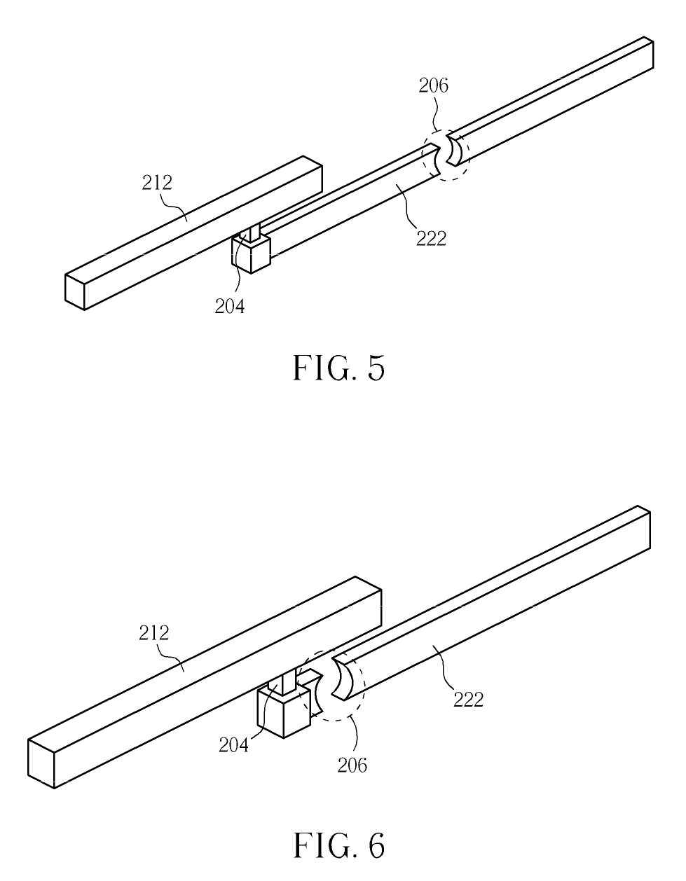

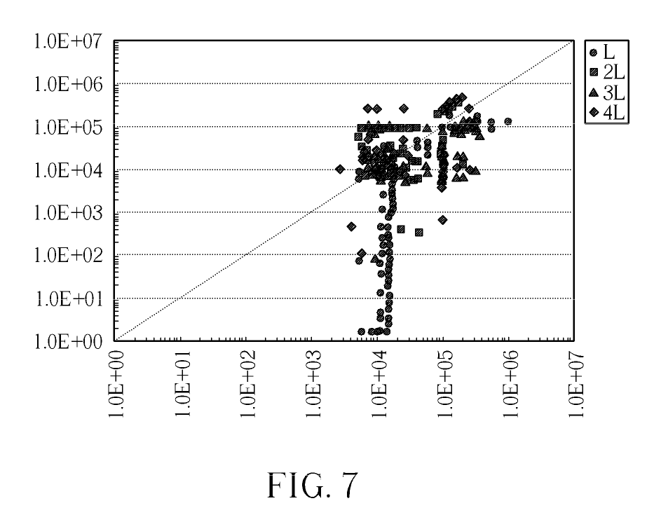

Please refer to FIG. 5 and FIG. 6, which are schematic drawings respectively illustrating the e-fuse structure of the preferred embodiment after performing a blowing process. Please note that for emphasizing the positions of the blowing point formed in the e-fuse structure 200, only the top fuse 212, the bottom fuse 222 and the via conductive layer 204 of the e-fuse structure 200 are depicted in FIG. 5 and FIG. 6 while elements such as the cathode 214 and the anode 224 of the e-fuse structure 200, the first dielectric layer 110, the second dielectric layer 112 and the metal interconnection structure 300 are all omitted. As shown in FIG. 5 and FIG. 6, the method for fabricating an e-fuse structure provided by the preferred embodiment can further include performing a blowing process, thus a blowing point 206 is formed in the bottom fuse 222 after the blowing process. More important, when the bottom fuse length L_{bottom} is more than twice the top fuse length Lₜₒₚ, the blowing point 206 is formed beyond the overlapping region 202 of the bottom fuse 222 and the top fuse 212 as shown in FIG. 5. And when the bottom fuse length L_{bottom} is 1-2 times the top fuse length Lₜₒₚ, the blowing point 206 is formed near the overlapping region 202 of the bottom fuse 222 and the top fuse 212, even in an overlapping region of the bottom fuse 222 and the via conductive layer 204. It is therefore concluded that the e-fuse structure 200 is shrank when the minimum blowing current is decreased.

It is concluded that according to the method for fabricating an e-fuse structure provided by the preferred embodiment, the top fuse length Lₜₒₚ, the bottom fuse length L_{bottom} and, and the scaling relation between the top fuse 212 and the bottom fuse 222 are decided according to the position where the blowing point 206 is to be formed before forming the top fuse 212 and the bottom fuse 222. Then, the top fuse 212 and the bottom fuse 222 are respectively formed in the second dielectric layer 110 and the first dielectric layer 112. Consequently, by adjusting the scaling relation between the top fuse length Lₜₒₚ and the bottom fuse length L_{bottom}, it is ensured that the blowing point 206 is formed in the expected position. Furthermore, a blowing time of the e-fuse structure 200 provided by the preferred embodiment is reduced to 1 micro second (μs) which is advantageous to the e-fuse structure 200. In addition, please refer to FIG. 7, which illustrates the relationship of metal fuse resistance between before and after a high temperature storage lifetime (HTSL) test of 150° C. and 168 hours. According to FIG. 7, when the bottom fuse length L_{bottom} is more than twice the top fuse length Lₜₒₚ, the fuse resistance deviation between before and after the HTSL test is not obvious. In other words, the e-fuse structure 200 provided by the preferred embodiment has a superior reliability.

According to the e-fuse structure and the method for fabricating the same provided by the top fuse length and the bottom fuse length are decided according to the position where the blowing point is formed: When the bottom fuse length is larger than the top fuse length, it is ensured that the blowing point is formed in the bottom fuse. Furthermore, in the condition that the bottom fuse length is larger than the top fuse length, the bottom fuse length and the top fuse length are further adjusted and formed such that the blowing point is formed near a boundary between the bottom fuse and the via conductive layer. Consequently, the size of the e-fuse structure is shrunk and the blowing window is increased.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electrical fuse (e-fuse) structure, comprising:
a top fuse having a top fuse length, and the top fuse length being equal to or larger than a predetermined value;
a bottom fuse having a bottom fuse length, and the bottom fuse length being larger than the top fuse length; and
a via conductive layer positioned between the top fuse and the bottom fuse for electrically connecting the top fuse and the bottom fuse.

2. The e-fuse structure according to claim 1, further comprising a cathode and an anode, the cathode is electrically connected to the top fuse and the anode is electrically connected to the bottom fuse.

3. The e-fuse structure according to claim 1, further comprising a first dielectric layer and a second dielectric layer, the bottom fuse is positioned in first dielectric layer, and the top fuse and the via conductive layer are positioned in the second dielectric layer.

4. The e-fuse structure according to claim 3, further comprising a first metal interconnection layer and a second metal interconnection layer stacked on the first metal interconnection layer, the first metal interconnection layer is positioned in the first dielectric layer and the second metal interconnection layer is positioned in the second dielectric layer.

5. The e-fuse structure according to claim 4, wherein the first metal interconnection layer and the bottom fuse are coplanar, and the second metal interconnection layer and the top fuse are coplanar.

6. The e-fuse structure according to claim 4, wherein the first metal interconnection layer is electrically isolated from the bottom fuse, and the second metal interconnection layer is electrically isolated from the top fuse.

7. The e-fuse structure according to claim 1, further comprising a blowing point formed in the bottom fuse after a blowing process.

8. The e-fuse structure according to claim 7, wherein the blowing point is formed beyond an overlapping region of the bottom fuse and the via conductive layer.

9. The e-fuse structure according to claim 8, wherein the bottom fuse length is more than twice the top fuse length.

10. The e-fuse structure according to claim 7, wherein the blowing point is formed in an overlapping region of bottom fuse and the via conductive layer.

11. The e-fuse structure according to claim 10, wherein the bottom fuse length is 1 to 2 times the top fuse length.

12. The e-fuse structure according to claim 1, wherein the predetermined value is 0.77 micrometer (μm).

13. A method for fabricating an electrical fuse (e-fuse) structure comprising:
providing a substrate;
forming a first metal interconnection layer and a bottom fuse on the substrate, the bottom fuse having a bottom fuse length;
forming a second metal interconnection layer, a top fuse, and a via conductive layer on the substrate, the top fuse having a top fuse length, and the top fuse length being equal to or larger than a predetermined value; wherein
the bottom fuse length is larger than the top fuse length.

14. The method for fabricating an e-fuse structure according to claim 13, further comprising forming an anode simultaneously with forming the bottom fuse and the first metal interconnection layer, and forming a cathode simultaneously with forming the top fuse and the second metal interconnection layer.

15. The method for fabricating an e-fuse structure according to claim 14, wherein the top fuse is electrically connected to the cathode, and the bottom fuse is electrically connected to the anode.

16. The method for fabricating an e-fuse structure according to claim 13, wherein the first metal interconnection layer is electrically isolated from the bottom fuse, and the second metal interconnection layer is electrically isolated from the top fuse.

17. The method for fabricating an e-fuse structure according to claim 13, further comprising performing a blowing process to form a blowing point in the bottom fuse.

18. The method for fabricating an e-fuse structure according to claim 17, wherein when the bottom fuse length is more than twice the top fuse length, the blowing point is formed beyond an overlapping region of the bottom fuse and the via conductive layer.

19. The method for fabricating an e-fuse structure according to claim 17, wherein when the bottom fuse length 1 to 2 times the top fuse length, the blowing point is formed in an overlapping region of the bottom fuse and the via conductive layer.

20. The method for fabricating an e-fuse structure according to claim 13, wherein the predetermined value is 0.77 μm.
